(19) United States
(12) Patent Application Publication
(10) Pub. No.: US 2009/0146231 A1
(43) Pub. Date: Jun. 11, 2009

(54) Magnetic memory device having a C-shaped structure and method of manufacturing the same

(76) Inventors: Cynthia A. Kuper, Villanova, PA (US); Darren Imai, Los Gatos, CA (US)

Correspondence Address: MORGAN LEWIS & BOCKIUS LLP, 1111 PENNSYLVANIA AVENUE NW, WASHINGTON, DC, 20004, US

(21) Appl. No.: 12/289,951

(22) Filed: Nov. 7, 2008

Related U.S. Application Data
(60) Provisional application No. 60/996,794, filed on Dec. 5, 2007.

(51) Int. Cl. H01L 29/82; H01L 21/00

(52) U.S. Cl. 257/421; 438/3; 257/E21.001; 257/E29.323

(57) ABSTRACT

A non-volatile magnetic memory device having one or more memory cells, each of the memory cells includes a magnetic switch including a C-shaped magnetic component and a write coil located proximate the magnetic component, the write coil coupled to receive a current sufficient to create a remnant magnetic polarity in the magnetic component, and a Hall sensor, positioned proximate the magnetic component, to detect the remnant magnetic polarity indicative of a stored data bit.

This application claims the benefit of pending U.S. provisional patent application No. 60/996,794, which was filed on Dec. 5, 2007 and is incorporated herein by reference in its entirety.

### FIELD OF THE INVENTION

The present invention relates to a memory device and, more particularly, to a memory device using magnetic memory elements.

### BACKGROUND OF THE INVENTION

The rapid growth in the portable consumer product market (including the products for portable computing and communications) is driving the need for low power consumption non-volatile memory devices, with their inherent ability to retain stored information without power. The principal technology currently available in the marketplace for these applications is EEPROM (Electrically Erasable Programmable Read-Only Memory) technology, relying on charging (writing) or discharging (erasing) the floating-gate of a Metal-Oxide-Semiconductor (N-type) type transistor using so-called Fowler-Nordheim tunneling through the ultra-thin oxide layer of these structures.

The charging of the gate creates results in an electron inversion channel in the device rendering it conductive (constituting a memory state 1). Discharging the floating gate (i.e., applying a negative bias) removes the electrons from the channel and returns the device to its initial non-conductive state (i.e., memory state 0). One serious limitation to this technology is related to tunneling that limits the erase/write cycle endurance and can induce catastrophic breakdown (after a maximum of about 10⁶ cycles). Moreover, the required charging time—which is of the order of 1 ms—is relatively long.

In order to improve performance, so-called FeRAM (Ferroelectric Random Access Memory) technology has been developed. The FeRAM memory cell consists of a bi-stable capacitor, and is comprised of a ferroelectric thin film that contains polarizable electric dipoles. These dipoles, analogous to the magnetic moments in a ferromagnetic material, respond to an applied electric field to create a net polarization in the direction of the applied field. A hysteresis loop for sweeping the applied field from positive to negative field defines the characteristics of the material; On removing the applied field, the ferroelectric material can retain a polarization known as the remnant polarization, serving as the basis for storing information in a non-volatile fashion. FeRAM would appear to be a promising technology with good future potential since relatively low voltages (typically about 5V) are required for switching as compared with about 12 to 15V for EEPROM. Moreover, FeRAM devices show 10⁸ to 10¹⁰ cycle write endurance compared with about 10⁶ for EEPROM, and the switching of the electrical polarization requires as little as about 100 ns compared with about 1 ms for charging an EEPROM. However, the need for an additional cycle to return a given bit to its original state for reading purposes aggravates the problems of dielectric fatigue. This, in turn, is characterized by degradation in the ability to polarize the material. In addition, owing to the behavior of these materials about their Curie temperature, as well as compositional stability (and associated changes in Curie temperature), even moderate thermal cycling promotes accelerated fatigue. Finally, fabrication process uniformity and control still remains a challenge.

Today, MRAM (Magnetoresistance Random Access Memory)—whose development began some 20 years ago—appears to hold the greatest promise for existing technologies in terms of read/write endurance cycle and speed. The technology relies on a writing process that uses the hysteresis loop of a ferromagnetic strip, while the reading process involves the anisotropic magnetoresistance effect. Basically, this effect (based on spin-orbit interaction) relates to the variation of the resistance of a magnetic conductor, dependent on an external applied magnetic field. The bit consists of a strip of two ferromagnetic films (e.g., NiFe) sandwiching a poor conductor (e.g., TaN), placed underneath an orthogonal conductive strip line (i.e., known as the word line). For writing, a current passes through the sandwich strip and when aided by a current in the orthogonal strip-line, the uppermost ferromagnetic layer of the sandwich strip is magnetized either clockwise, or counterclockwise. Reading is performed by measuring the magnetoresistance of the sandwich structure (i.e., by passing a current). Magnetoresistance ratios of only about 0.5% are typical, but have allowed the fabrication of a 16 Kb MRAM chip operating with write times of 100 ns (and read times of 250 ns). A 250 Kb chip was also later produced by Honeywell.

The discovery of so-called Giant Magnetoresistance (GMR) in 1989, implemented by sandwiching a copper layer with a magnetic thin film permitted further improvement in memory device performance. The GMR structures showed a magnetoresistance of about 6%, but the exchange between the magnetic layers limited how quickly the magnetization could change direction. Moreover magnetization curling from the edge of the strip imposed a limitation on the reduction in the cell size, or scaling.

Promising results were then obtained with the so called Pseudo-Spin Valve (PSV) cell made of a sandwich structure with two magnetic layers mismatched so that one layer tends to switch magnetization at a lower field than the other. The soft film is used to sense (by the magnetoresistance effect) the magnetization of the hard film—this latter film constitutes the storage media, having magnetization of either up or down (i.e., states 0 or 1). PSV structures are amenable to scaling but the reported fields required to switch the hard magnetic layer are still too high for high density integrated circuits. These devices appear to potentially represent a replacement for EEPROMs.

Further improvements in magnetoresistance (i.e., up to 40%) are obtained with spin-dependent tunneling devices (SDT). These devices are made of an insulating layer (i.e., the tunneling barrier) sandwiched between two magnetic layers. Device operation relies on the fact that the tunneling resistance, in the direction perpendicular to the stack, depends on the magnetization of the magnetic layers. The highest resistance is obtained when the magnetization of the layers is anti-parallel, and the parallel case provides the lowest resistance. The variation of spin (i.e., up or down) state density between the two magnetic layers explains this behavior. One of the layers is pinned while the second magnetic layer is free and used as the information storage media. SDT show promise for high performance non-volatile applications. Indeed there have been some reported values for write times as small as 14 ns with this approach. However, controlling the resistance uniformity (i.e., the tunneling barrier thickness and quality), and hence controlling the switching behavior from bit to bit remains a real challenge that has yet to be overcome in practical implementation. What is needed is a non-volatile memory device that is fast, reliable, relatively simple in design, inexpensive, and robust.

### SUMMARY OF THE INVENTION

Accordingly, the present invention is directed to a magnetic memory device that substantially obviates one or more of the problems due to limitations and disadvantages of the related art.

An object of the present invention is to provide a magnetic switch used to form a memory cell in a non-volatile magnetic memory device.

Another object of the present invention is to provide a simplified method of fabricating a non-volatile magnetic memory device.

Additional features and advantages of the invention will be set forth in the description that follows and, in part, will be apparent from the description or may be learned by practice of the invention. The objectives and other advantages of the invention will be realized and attained by the structure particularly pointed out in the written description and claims herein as well as the appended drawings.

To achieve these and other advantages and in accordance with the purpose of the present invention, as embodied and broadly described, a non-volatile magnetic memory device having one or more memory cells, each of the memory cells includes a magnetic switch including a magnetic component and a write coil located proximate the magnetic component, the write coil coupled to receive a current sufficient to create a remnant magnetic polarity in the magnetic component, and a Hall sensor, positioned proximate the magnetic component, to detect the remnant magnetic polarity indicative of a stored data bit.

In another aspect of the invention, a method of fabricating one or more memory cells of a non-volatile magnetic memory device, the steps include forming a magnetic switch including a magnetic component and a write coil located proximate the magnetic component, the write coil coupled to receive a current sufficient to create a remnant magnetic polarity in the magnetic component, and forming a Hall sensor, positioned proximate the magnetic component, to detect the remnant magnetic polarity indicative of a stored data bit.

In yet another aspect of the invention, a method of fabricating a magnetic switch of a memory cell in a non-volatile magnetic memory device, the steps include forming one or more write coils and electroplating or depositing by way of PVD or evaporation a magnetic material to form a magnetic component located proximate to the write coil(s), the write coil(s) coupled to receive a current sufficient to create a remnant magnetic polarity in the magnetic component.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 shows a schematic view of an exemplary embodiment of a memory cell in accordance with the present invention.

FIGS. 2A and 2B show a side view of an exemplary embodiment of a magnetic switch in accordance with the present invention.

FIG. 3 shows an exemplary embodiment of an electroplating system in accordance with the present invention.

FIGS. 4A-4H show various exemplary stages of fabrication for the lower portion of an exemplary magnetic switch in accordance with the present invention.

FIGS. 5A-5I show various exemplary stages of fabrication for an exemplary sensor in accordance with the present invention.

FIGS. 6A-6E show various exemplary stages of a fabrication process (i.e., lift-off) for an exemplary coil in accordance with the present invention.

FIGS. 7A-7D show various exemplary stages of fabrication for the upper portion of an exemplary magnetic switch in accordance with the present invention.

FIGS. 8A-8E show various exemplary stages of an alternative fabrication process (i.e., direct etching) for an exemplary coil in accordance with the present invention.

FIGS. 9A-9F show various exemplary stages of an alternative fabrication process for an exemplary magnetic switch in accordance with the present invention.

### DETAILED DESCRIPTION OF THE PREFERRED EMBODIMENTS

Reference will now be made in detail to the preferred embodiments of the present invention, examples of which are illustrated in the accompanying drawings.

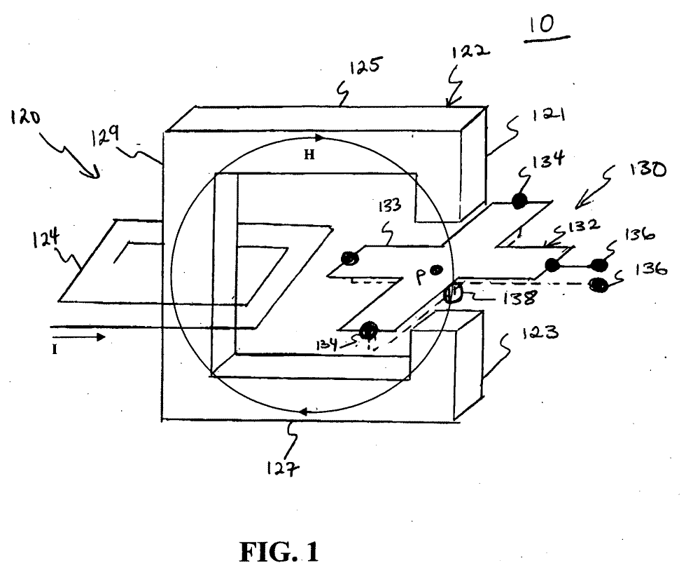

The present invention is directed to a magnetic memory device. In particular, FIG. 1 illustrates an exemplary embodiment of a memory cell of a magnetic memory device according to the present invention. A memory cell 10 according to an exemplary embodiment of the present invention includes a magnetic switch 120 and a sensor 130. The magnetic switch 120 includes a generally C-shaped magnetic component or material 122 and a coaxial coil 124 around one of the legs of the C-shaped magnetic component 122 to hold data. The sensor 130 includes a Hall effect sensor 132 and output terminals 136 connected to a voltage detector (not shown) to detect the stored data in the magnetic switch 120.

The C-shaped magnetic component 122 includes an upper leg 125, a lower leg 127, and a side leg 129. The upper and lower legs 125, 127 include upper and lower magnetic poles 121, 123, respectively. The magnetic component 122 may be a permanent magnet or a ferromagnetic material (e.g., nickel or nickel-iron magnet). The coaxial coil 124 (connected to a current source, not shown) is disposed about the side leg 129 of the magnetic component 122. The coil 124 is made of a conductive material, such as the metal copper or aluminum. However, any other suitable conductive material (e.g., TiN/Ti/Cu or TaN/Ta/Cu) may be used without departing from the scope of the present invention.

The upper and lower magnetic poles 121, 123 of the magnetic component 122 is disposed perpendicularly to the Hall effect sensor 132 and is aligned with one of the sensor's current-carrying arms 133. In particular, the upper magnetic pole 121 is located above the central active region P of the Hall sensor 132 and the lower magnetic pole 123 is located below the central active region P.

The Hall effect sensor 132 includes a geometrically defined semiconductor structure with input terminals 134 connected to power supply 138 and output terminals 136 positioned perpendicularly to the direction of current flow. Although the Hall effect sensor 132 is shown as having a “Greek cross” shape for purposes of illustration, any suitable shape (e.g., rectangle) may be used without departing from the scope of the present invention.

In general, Hall effect sensors respond to a physical quantity to be sensed (i.e., magnetic induction) through an input interface and, in turn, outputs the sensed signal to an output interface that converts the electrical signal from the Hall effect sensor into a designated indicator. In the present case, when the Hall effect sensor 132 is subjected to a magnetic field (H) from the upper and lower poles 121, 123 of the magnetic component 122, a potential difference appears across the output terminals 136 in proportion to the field strength. When the Hall effect sensor 132 is subjected to an equal and opposite magnetic field, an equal and opposite potential difference appears across the same output terminals 136. The Hall effect sensor 132 thus acts as a sensor of both the magnitude and direction of an externally applied magnetic field.

In general, the shape and material used for magnetic switch 120 determines the strength of magnetization (M) responsible for generating a magnetic field (H) around sensor 130. The number of turns of the coil 124 around the side leg 129, together with the current (I) applied to the coil 124, determines the strength of the induced magnetization (H) generated around the magnetic component 122 to set the direction and intensity of the magnetization (M). The direction of the magnetization (M) of the magnetic component 122 determines the value of the stored data (i.e., “0” or “1”) in the magnetic switch 120. The Hall effect sensor 132 is characterized by voltage signal V^{Hall} that is generated in response to the magnetic field (H) emanating from the magnetic component 122 detected at point P.

A current (I) (e.g., current pulse) is sent through the coil 124 in such a way as to generate a magnetic field H_{wire}. The magnitude of the current is chosen to be sufficient to change (i.e., flip) the magnetization of the magnetic component 122. The magnetic field generated by the magnetic component 122 needs to be sufficient for the sensor 130 to detect it at detection point P. After detection, sensor 130 needs to generate a response (V_{Hall}) greater than an offset voltage signal V_{Off}. An offset voltage V_{off} is the threshold that must be overcome before any useful signals are generated.

More specifically, the magnetic field (H) generated by the magnetization (M) of magnetic switch 120 must be strong enough at point P to generate an induced voltage in sensor 130 greater than V_{Off} before the stored data can be accurately detected. A magnetic field that generates a voltage signal less than the offset voltage cannot be detected by the sensor 130 in the present DC bias conditions.

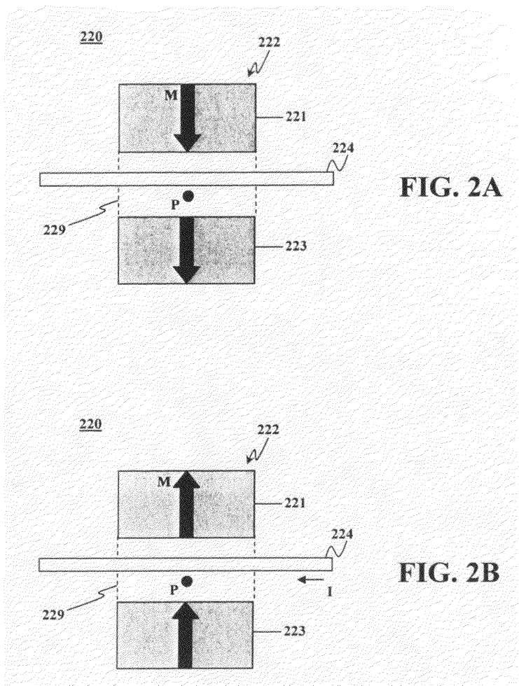

FIGS. 2A and 2B show a side view of an exemplary embodiment of a C-shaped magnetic component and coil. FIG. 2A shows a side view of a magnetic component 222 having an upper pole 221 and a lower pole 223 having an initial direction of magnetization (M) oriented downward. FIG. 2B shows that after a sufficiently high current (I) is sent through the coil 224, the magnetic component 222 retains an induced magnetization whose direction is oriented upward. In this case, the magnetic induction proximate to the surface of the magnetic component 222, at detection point P, is the field generated by the magnetic component 222. This field causes the sensor 130 (FIG. 1) to generate a voltage signal that should have a magnitude greater than the voltage signal V_{Off} and a sign indicating the direction of magnetization (e.g., a positive voltage for “upward”). If an upward magnetization is designated as “1,” then the sensor 130 detects the stored data as being “1.”

To then attain a downward magnetization (i.e., “0”), a suitable current (e.g., current pulse in the opposite direction) is again sent through the coil 224 to generate a magnetic field −H_{wire} (i.e., opposite orientation than H_{wire}) sufficient to change (i.e., flip) the magnetization of the magnetic component 222. After the current pulse, the magnetic component 222 retains a magnetization that may have smaller magnitude or whose direction is oriented downward. In this case, the magnetic field at detection point P is the magnetic field generated by the magnetic component 222. The detected induction at point P causes the sensor 130 (FIG. 1) to generate a voltage signal that has a smaller magnitude or opposite sign indicating the direction of magnetization (e.g., a negative voltage for “downward”). If a downward or smaller magnetization is designated as “0,” then the sensor 130 detects the stored data as being “0.”

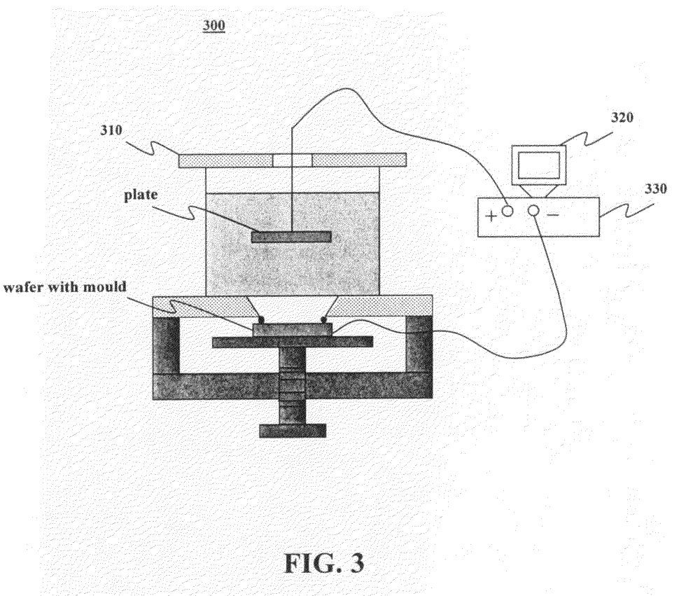

The fabrication process will now be explained with reference to FIGS. 3, 4A-4H, 5A-5I, 6A-6E, 7A-7D, 8A-8E, and 9A-9F. The fabrication process of the memory cell 10 (as shown in FIG. 1) may be divided into 3 parts: (1) fabrication of the lower portion of the magnetic switch 120, (2) fabrication of the sensor 130, and (3) fabrication of the upper portion of the magnetic switch 120.

Traditional methods for fabricating magnetic materials (e.g., Alnico and Martensitic steel) involve synthesis routes that include, for example, melting different components, casting, and high temperature (typically, above 800° C.) thermal processing (e.g., quenching). Other synthesis routes include sintering and extrusion. These methods are incompatible with micro-technology or wafer-scale processing due to the extremely small sizes of the components. Electroplating, on the other hand, allows for relatively good definition of element shapes with fewer defects on element walls. It is also an inexpensive and relatively simple process to implement. Three-electrode systems can be used to monitor the stoichiometry of deposited alloys.

In an exemplary embodiment of the present invention, electroplating will be used in the fabrication process of the magnetic switch 120. However, any suitable synthesis route may be utilized (e.g., physical vapor deposition, evaporation) without departing from the scope of the present invention. As shown in FIG. 3, an electroplating system 300 includes an electroplating cell 310, a computer 320, and a computer-driven potentiostat/galvanostat 330. The computer 320 is connected to the electroplating cell 310 through the potentiostat/galvanostat 330 to control the electroplating process. The potentiostat/galvanostat 330 can function as either a potentiostat or a galvanostat.

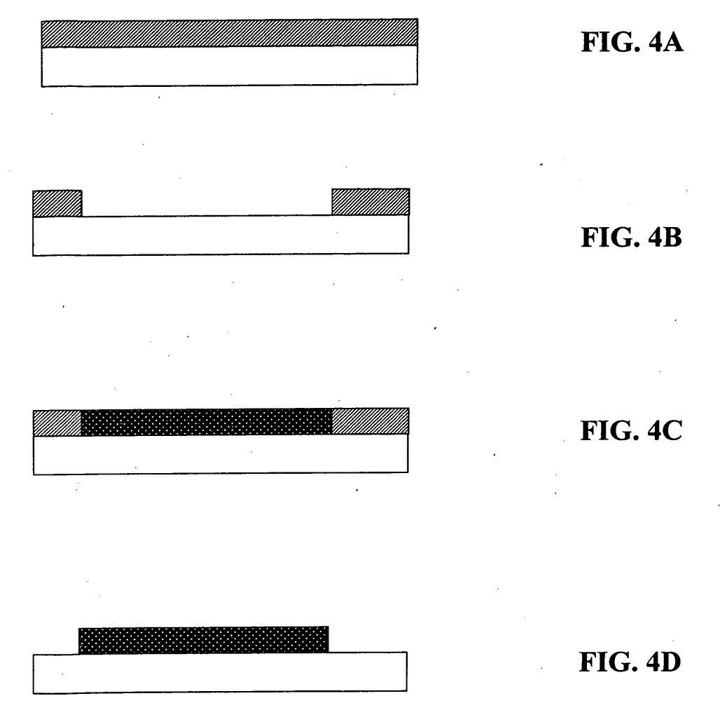

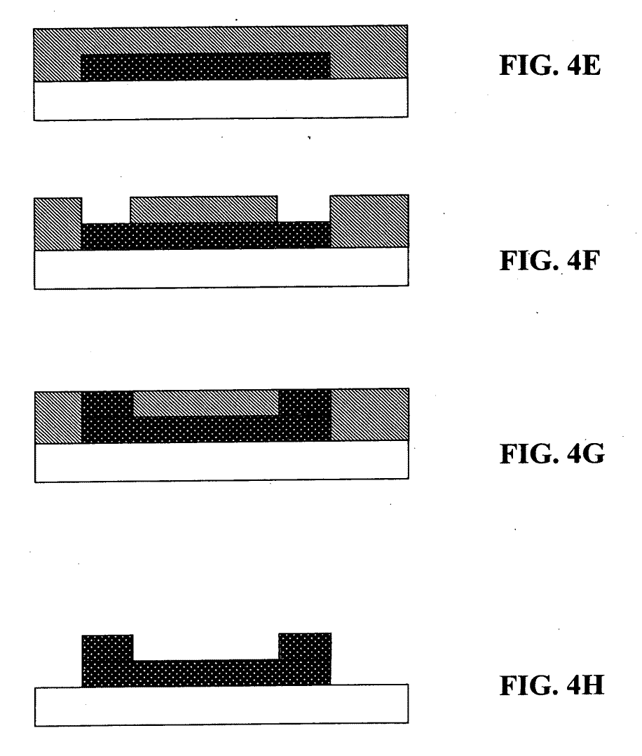

FIGS. 4A-4H illustrate various exemplary stages of a fabrication process for the lower portion of the magnetic switch 120 in accordance with an exemplary embodiment of the present invention. In particular, the fabrication process shown in FIGS. 4A-4H is a through-hole plating process. However, other processes, such as window frame plating, reactive ion etching (RIE) lift-off or ion-milling, may be used without departing from the scope of the present invention. A suitable wafer 438, such as an insulating wafer is used. A conductive seed layer, such as NiFe is sputtered onto the surface of the wafer. NiFe is used as an example, but any conductive seed layer such as TaN/Ta/Cu can be used without departing from the scope of this invention. In general, the lower leg 127 is electroplated onto the wafer 438 through a mold that provides the shape and dimensions of the lower leg 127.

As shown in FIGS. 4A-4D, to fabricate such a mold, photolithography may be used to pattern a thick layer 440 of resist (e.g., 1 to 10 μm of AZ4620 depending of the thickness to be plated, but any kind of photoresist process: broadband, i-line, 248 nm or 193 nm, can be used and the process adapted from the manufacturer's suggested process instructions for the resist system chosen) onto the wafer 438. The resist layer 440 is baked at about 95° C. for about 4 minutes. Then, the resist layer 440 is exposed to ultraviolet light to form a well 441, which provides the shape for the lower leg 127. Following this exposure, the resist layer 440 is developed in a suitable solution, such as PPD 450, to obtain the well 441. (FIG. 4B.) The well 441 serves as a container into which a magnetic material 442 is to be electroplated to form the lower leg 127.

The wafer 438 with the resist template is then placed into the electroplating cell 310 (FIG. 3), where pulsed deposition (with, e.g., a 2% duty cycle, where tₒₙ=1 ms; t_{off}=49 ms; and the peak current is about 1.4 mA) or DC deposition (many processes are described in the literature, especially in relation to magnetic recording) is used to deposit the magnetic material 442 (e.g., nickel or nickel-iron) onto the resist template forming the well 441 to thereby form an array of lower legs 127. (FIG. 4C.) While pure materials are generally easier to deposit, alloys may also be used without departing from the scope of the present invention. Examples of materials that may be used include cobalt, iron, nickel, nickel-iron (NiFe), and cobalt-nickel-iron (CoNiFe). Different catalysts may be used to increase or decrease the coercivity of these materials if needed, depending on the ease of switching the magnetization, and the stability of the magnetic bit required (e.g. stray EM radiation resistance).

For illustrative purposes, a nickel chloride based solution with two additives, namely saccharin (which acts as a strain relief agent) and sodium lauryl sulfate (which acts as a surfactant), is deposited into the well 441. A current, such as a DC current, is used to fabricate the lower leg 127. For an even smaller, higher aspect ratio structure, pulsed electro-deposition (with, e.g., a 2% duty cycle) may be used to deposit the magnetic material 442 (e.g., nickel or nickel-iron) onto the resist template to form an array of lower legs 127. The electroplating conditions are controlled by the computer-driven potentiostat/galvanostat 330. After electro-deposition, the mold (i.e., thick resist layer 440) is removed using a suitable solution, such as acetone or any other commercially available resist stripper. (FIG. 4D.)

Once the mold is removed, magnetic pillars 448a, 448b are formed over the lower leg 127. Like the lower leg 127, the magnetic pillars 448a, 448b are electroplated onto the wafer 438 through a mold that provides the shape and dimensions of the magnetic pillars 448a, 448b. FIGS. 4E-4H illustrates an exemplary fabrication process for the magnetic pillars 448a, 448b.

First, using lithography, for example, a mold is fabricated by patterning a thick layer 444 of resist (e.g., 1 to 10 μm of AZ4620 depending on the wafer topography and intended plating thickness) to form wells 445a, 445b, which provide the shapes for the magnetic pillars 448a, 448b. (FIG. 4F.) Next, a magnetic material 446 (e.g., nickel or nickel-iron) is deposited into the wells 445a, 445b. (FIG. 4G.) Finally, the mold (i.e., thick resist layer 444) is removed using a suitable solution, such as acetone or resist stripper to form the magnetic pillars 448a, 448b. (FIG. 4H.) The magnetic pillar 448a forms the lower portion of the side leg 129 and the magnetic pillar 448b forms the lower magnetic pole 123 of the magnetic component 122 (shown in FIG. 1). The conductive seed layer is now removed using sputter etching, RIE, or other etching process (wet or dry depending on the seed material).

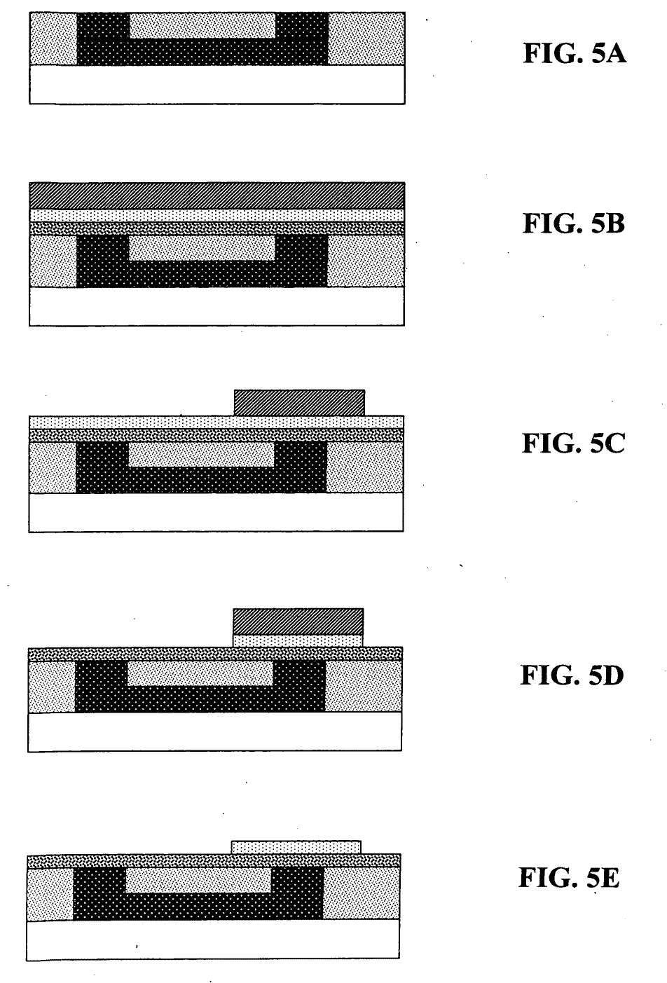

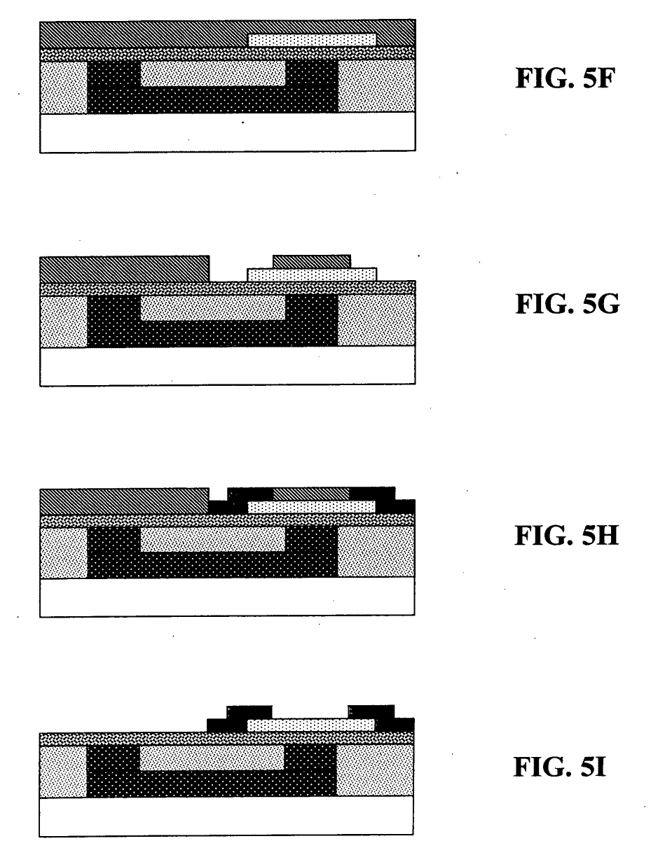

Once the lower portion of the magnetic switch 120 is formed, the sensor 130 is formed over the lower portion of the magnetic component. The fabrication process for the sensor 130 will be explained with reference to FIGS. 5A-5I.

The Hall effect sensor 132 is fabricated with high mobility materials, such as group IV and III-V materials (i.e., compounds formed from group IV like SiGe, or group III and V elements of the periodic table). Examples of group IV and III-V materials include, but are not limited to, SiGE, GaAs, InAs, InSb, and related two-dimensional electron gas (2DEG) structures. A 2DEG structure based on a GaAs/AlGaAs hetero-structure may be formed at the hetero junction interface of a modulation-doped hetero-structure between a doped wide band-gap AlGaAs material (i.e., barrier) and an undoped narrow band-gap GaAs material (i.e., well). Ionized carriers (from the dopant) transfer into the well, forming the 2DEG. These carriers are spatially separated from their ionized parent impurities and, therefore, allow for high carrier mobility and a large Hall effect. Although only IV and III-V materials are discussed here, other materials (e.g., silicon) may be used to fabricate the Hall effect sensor 132.

FIGS. 5A-5E illustrate the various exemplary fabrication stages of the Hall effect sensor 132 in accordance with an exemplary embodiment of the present invention. The wafer 438 having formed thereon the lower portion of the magnetic component 122 is coated with a layer 550 of a dielectric material, such as silicon dioxide or TEOS. The wafer 438 is then planarized using chemical-mechanical planarization (or chemical-mechanical polishing) or other lapping/polishing techniques. During this planarization the top portions of the magnetic pillars 448a and 448b are exposed. After planarization, a thin (about 0.5-0.6 μm) crystalline n-type active GaAs film or layer 552b for the Hall sensor 132 is to be deposited onto the wafer 438. However, silicon dioxide is not a compatible crystal substrate onto which crystalline GaAs can be deposited or grown because silicon dioxide and crystalline GaAs do not have the same lattice structure.

Accordingly, an interface layer 552a either a compliant layer as described in the literature or a low temperature amorphous GaAs which is deposited onto the wafer 438 before the crystalline GaAs layer 552b is deposited onto the wafer 438. The amorphous GaAs layer 552a is deposited onto the wafer 438 using physical vapor deposition (PVD), plasma enhanced chemical vapor deposition (PECVD), or other low temperature deposition process. After the amorphous GaAs layer 552a has been deposited on the wafer 438, heat at a temperature of about 580° C., for example, is applied to the wafer 438. An external magnetic field may be used to orient the magnetic material for proper hysteresis characteristics in the lower leg. As a result, the amorphous GaAs layer 552a is annealed (i.e., the amorphous GaAs layer 552a fuses with the silicon dioxide layer 550) and becomes semi-insulating at the same time.

Once the interface layer 552a of amorphous GaAs layer has been formed, the crystalline GaAs layer 552b can then be grown onto the wafer 438 through epitaxy since the amorphous GaAs layer 552a is a compatible substrate onto which crystalline GaAs can be grown. Here, the amorphous GaAs layer 552a serves as an interface between the silicon dioxide layer 550 and crystalline or epitaxial GaAs layer 552b while also serving as a buffer zone or semi-insulator between the silicon dioxide layer 550 and epitaxial GaAs layer 552b. As an insulator, the amorphous GaAs layer 552a electrically separates the lower magnetic pole 123 from the Hall sensor 132.

Following the growth of the epitaxial GaAs layer 552b, a layer 554 of resist is spun onto the wafer 438. (FIG. 5B.) Any suitable patterning technique (e.g., photolithography with any standard broadband, i-line, 248 nm or 193 nm photoresist) may be used without departing from the scope of the invention. A mesa etch process is then carried out for forming the Hall sensor 132. The etch process involves wet etching with, for example, a standard H₂O₂/H₃PO₄/H₂O solution or ion isolation by ion implant. (FIG. 5C-5D.) All resist residue is then removed. (FIG. 5E.)

Following the etching process, the input terminals 134 and output terminals 136 (FIG. 1) are deposited using a lift-off process, for example. As shown in FIGS. 5F-5I, the lift-off process involves spinning a layer 556 made of a double layer copolymer/PMMA (at 4000 rpm), but any lift-off structure using a double layer resist system or a single layer lift-off resist such as AZ® nLOF™ can be used without departing from the current invention. (FIG. 5F.) As used herein, the term “AZnLOF,” “AZ®nLOF™,” and “AZ nLof” are used synonymously and refer to AZ Electronics Materials' 2000 series i-line photoresists formulated for use in lift-off lithography processes. In various illustrative, non-limiting embodiments, the nLOF 2000 series photoresists work in both surfactant and non-surfactant containing tetramethylammonium hydroxide (TMAH) developers using standard conditions. In various illustrative, non-limiting embodiments, the nLOF 2000 series photoresists can be used for coating thicknesses beyond 7.0 μm and achieving aspect ratios of up to 4:1. The lift-off profile (i.e., under-etching) is provided by the difference of sensitivity between the copolymer and the PMMA during the development process and after the exposition to an electron beam. (FIG. 5G.) A contact layer 558 of suitable material, such as Mo or NiPd is evaporated onto the wafer 438 to a thickness of about 400 nm to form ohmic contacts 134, 136 to be used as input and output terminals of sensor 130. (FIG. 5H.). Other suitable materials for the contact layer 558 include Ti, TiW, W, Ta, Mo, or any metal silicide which is nonmagnetic.

Following the evaporation step, the lift-off process is completed by placing the wafer 438 in resist stripping solution with or without megasonic or ultrasonic transducers in order to remove any unnecessary portions of the ohmic contact layer 558. (FIG. 5I.) After appropriate cleaning, the contacts (i.e., ohmic contact layer 558) undergo rapid thermal annealing (RTA). The annealing is carried out at about 340° C. for about 40 seconds in an RTA chamber filled in nitrogen (N₂) flow. The lift-off process is completed by placing the wafer 438 in resist stripping solution in order to remove any unnecessary portions of the ohmic contact layer 558 remaining.

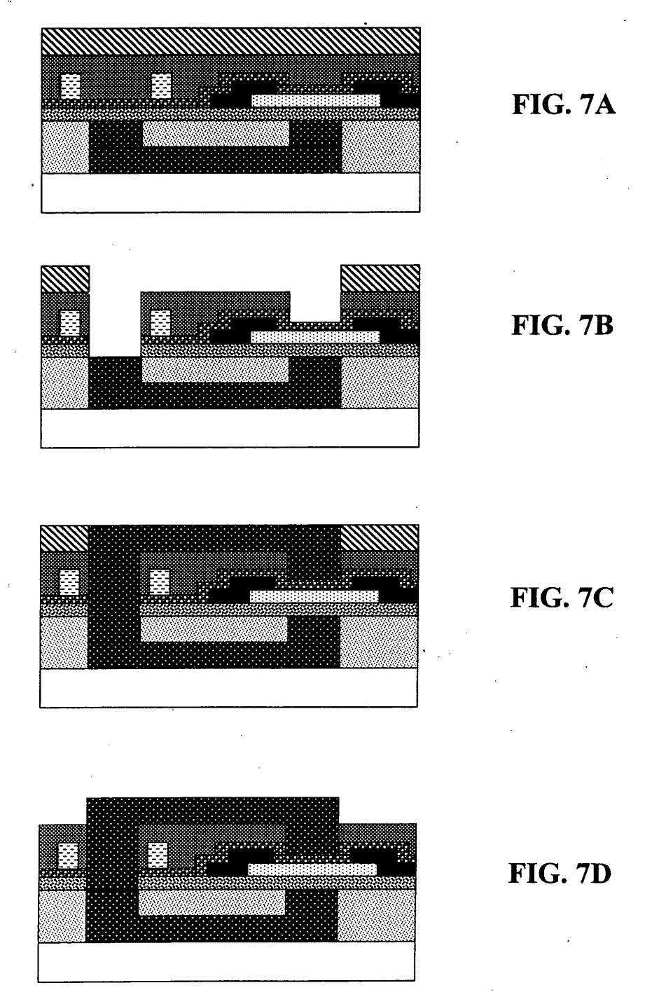

Once the sensor 130 is fabricated, the upper portion of the magnetic switch 120 is formed over the sensor 130. The general approach to fabricating the upper portion of the magnetic switch 120 is first to fabricate the coil 124 and then to fabricate the upper portion of the magnetic component 122. FIGS. 7A-7D illustrate various exemplary stages of a fabrication process for the upper portion of the magnetic switch 120 in accordance with an exemplary embodiment of the present invention.

An insulating layer 660 is deposited onto the wafer 438 having formed thereon the lower portion of the magnetic component 122 and Hall effect sensor 132. The insulating layer 660 is patterned using any suitable etching technique. The insulating layer 660 is made of a suitable material, such as a dielectric PECVD silicon nitride. Other suitable materials include silicon oxide, SiON, SiO₂, or SiO₂/Si₃Nₓ, which may be deposited through Plasma Enhanced Chemical Vapor Deposition (PECVD), PVD, or other low temperature deposition process.

For illustrative purposes only, the insulating layer 660 is a layer of PECVD silicon nitride is deposited onto the Hall effect sensor 132. Once the insulating layer 660 is deposited, a positive resist layer (not shown) (e.g., Az5206) is spun onto the insulating layer 660. The resist layer is then baked in an oven or hot plate at a temperature of 95° C. for two (2) minutes. The resist layer (not shown) is patterned in such a way as to make openings over the Hall effect sensor's ohmic contacts and alignment marks (if any).

After exposure, the resist layer (not shown) is developed in a suitable solution, such as TMAH for a suitable amount of time (e.g., about 60 seconds). The wafer 438 is then rinsed in de-ionized water. Once the wafer 438 is dried, an RIE process is used for etching the insulating layer 660 for a suitable amount of time to open vias down through the insulating layer 660. The resist layer is then removed using a standard resist stripping process.

After the insulating layer 660 is patterned, the coil 124 according to the present invention is fabricated over the insulating layer 660. The coil 124 is shown for purposes of illustration as having two turns around the side leg 129. (FIG. 1.) However, any suitable number of turns may be used without departing from the scope of the present invention. Because increasing the number of turns also increases the size of each memory cell, the coils may be layered to increase the number of turns while reducing the footprint of the coil 124 (e.g., two layers of single-turn coils). The coil 124 is made of a conductive material, such as the metal Al or copper. However, any other suitable conductive material (e.g., Ti/Cu/Ti) may be used without departing from the scope of the present invention.

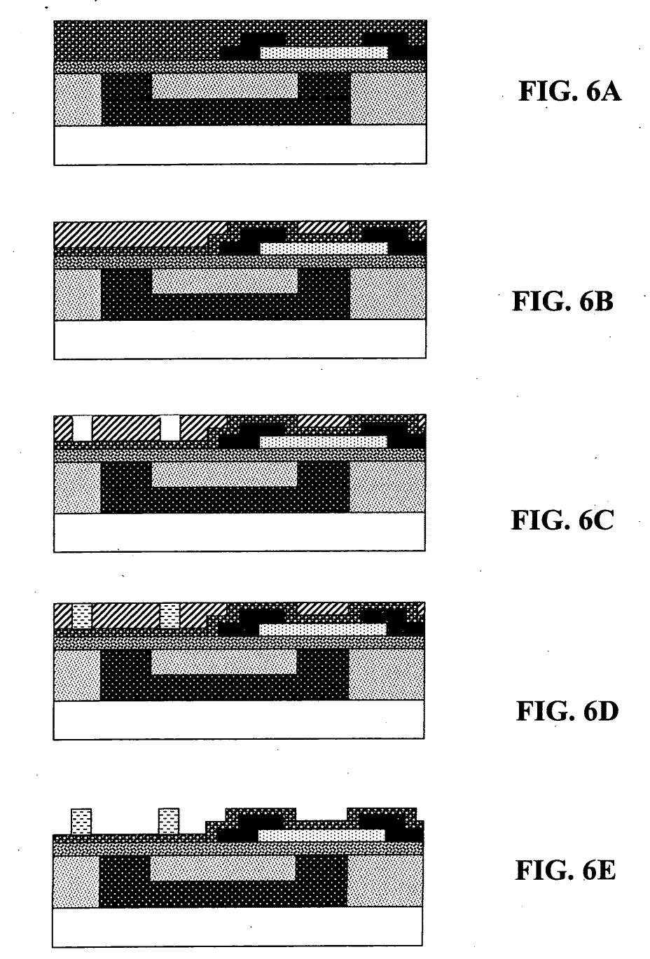

The fabrication process for the coil 124 will now be discussed with reference to FIGS. 6B-6E. An exemplary process for forming the coil 124 involves a titanium/copper lift-off process. However, other suitable processes include PVD, evaporation, or electroplating copper or other conducting materials.

A single or double layer lift-off structure is patterned using a process similar to the one explained earlier. After the patterning step, the wafer 438 is placed into an electron beam evaporator, where a titanium layer and a copper layer of 25 to 50 nm and 150 nm to 1 um, respectively, for example, are deposited onto the patterns to form a Ti/Copper layer 664. The titanium layer is used as an adhesion layer. Finally, the wafer 438 is removed from the evaporator and placed into a lift-off tank containing a resist stripper with or without megasonic or ultrasonic transducers to remove the lift-off layer 662 and any unwanted Ti/Cu metal layer. As shown in FIG. 6E, the coil 624 (which corresponds to coil 124 in FIG. 1) is obtained. In this exemplary embodiment, only a single-turn coil is shown. However, a coil with any number of turns may be formed as appropriate without departing from the scope of the invention. A lift-off process was explained here, but a deposition/etch process (e.g. aluminum/RIE) could also be used without departing from the current invention.

As shown in FIG. 7A, after depositing the coil 624, an insulating layer 765 is deposited onto the wafer 438 and planarized as discussed above. Vias are patterned and etched to open contacts down to the sensor terminal ohmic contacts and to open contacts to the back magnetic leg of the lower magnetic structure and to the top of the Hall sensor. The vias are then etched into the dielectric layer using RIE.

The upper portion of the magnetic component 122 is to be electroplated onto the wafer 438 using a mold that provides the shape and dimensions of the upper portion of the magnetic component 122. First a conductive seed layer is deposited onto the wafer to enable the electroplating to occur. The seed layer should be thick enough to give a good spreading resistance for plating uniformity, but should be as thin as possible to reduce spacing losses of the magnetic flux at the sensor. To fabricate such a mold, standard lithography, is used to pattern a thick layer 766 of resist (e.g., about 2 to 10/m of AZ4620) onto the planarized coil 624. The resist layer 766 is patterned and the wafer 438 is developed in order to obtain a well 768. (FIG. 7B.) The well 768 functions as a container into which a magnetic material 770 is to be electroplated to form the upper portion of the magnetic component 122.

The wafer 438 with the resist template is then placed into the electroplating cell 310 (FIG. 3) where pulsed deposition (with, e.g., a 2% duty cycle, where tₒₙ=1 ms; t_{off}=49 ms; and the peak current is about 1.4 mA) of straight DC deposition is used to deposit the magnetic material 770 (e.g., nickel or nickel-iron) onto the resist template with the well 768 to thereby form an array of upper portions of magnetic component 122. (FIG. 7C.)

For illustrative purposes only, as with the lower portion of the magnetic component 122, a nickel chloride based solution with two additives, namely saccharin (which acts as a strain relief agent) and sodium lauryl sulfate (which acts as a surfactant), is deposited into the well 768. A current, such as a DC current, is used to fabricate the upper portion of the magnetic component 122. For an even smaller, higher aspect ratio structure, pulsed electro-deposition (with, e.g., a 2% duty cycle) may be used to deposit the magnetic material 770 (e.g., nickel or nickel-iron) onto the resist template to form an array of upper portions of magnetic component 122. The electroplating conditions are controlled by the computer-driven potentiostat/galvanostat 330. After electro-deposition, the mold (i.e., thick resist layer 766) is removed using a suitable solution. (FIG. 7D.) Extra magnetic material can be deposited on the upper leg 125 of the magnetic component 122 to move the saturation point down to the pole area 121. The conductive seed layer is removed using RIE, ion milling or sputter etching. The memory switch 120 is then covered with a suitable passivation or insulating material (not shown).

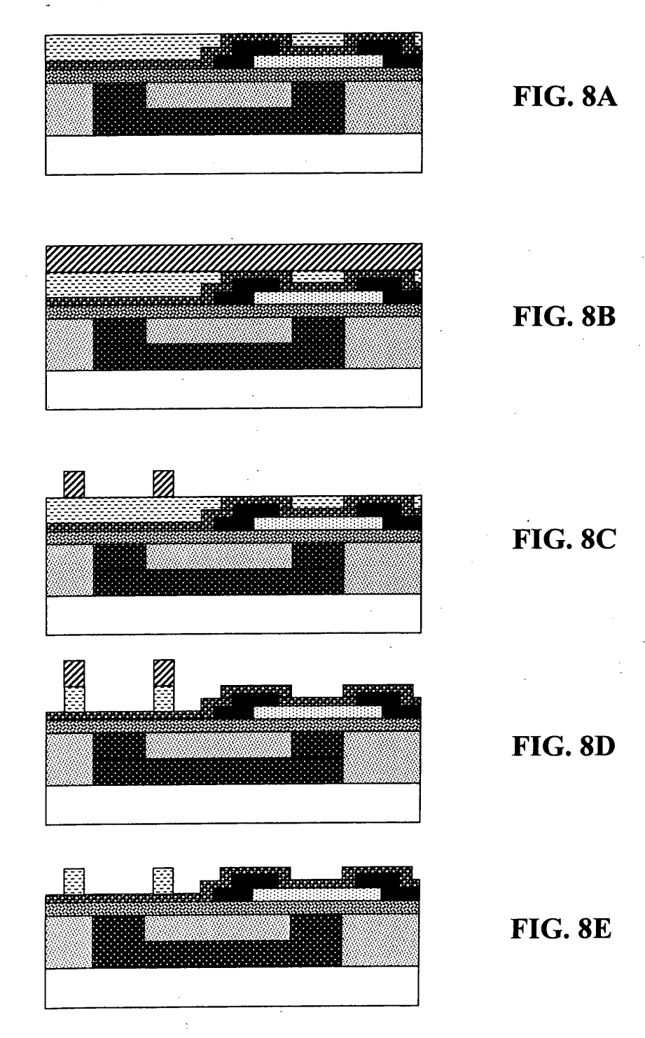

FIGS. 8A-8E illustrates an alternative exemplary embodiment for fabricating the coil 124. The alternative fabrication process involves etching directly a conductive layer 864. For example, after the patterning process of the insulating layer 660 (FIG. 6A), the wafer 438 is formed with a conductive layer 864 (e.g., Al layer). (FIG. 8A.) The wafer 438 carrying the conductive layer 864 is then patterned through, for example, standard UV resist processing. This patterning step can incorporate the use of a positive resist layer 872 and dry etching such as RIE etching. (FIG. 8B.) Again, the pattern includes a single-turn coil with a metallic path linking it electrically to a common electrode used for electroplating. However, any suitable number of turns may be used.

The aluminum layer, which forms the conductive layer 864, is etched with a suitable RIE processes. (FIG. 8D.) For example, the aluminum layer may be etched with a chlorine chemistry. The wafer 438 is then processed through a standard resist stripping process to remove the resist 872. (FIG. 8E.) Once the coil 824 has been etched directly into the conductive layer 864, the wafer 438 undergoes the processes for passivation, planarization, via etching and creating the mold for electroplating the magnetic component 122 as described above. The lower portion of the magnetic component 122 may also be fabricated using this approach.

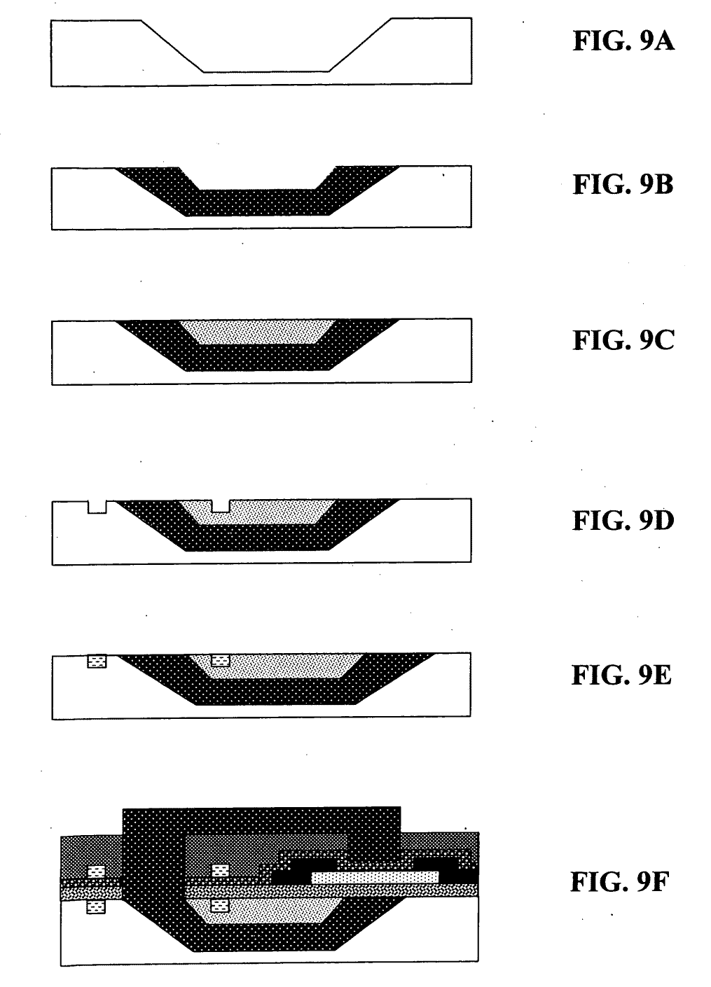

FIGS. 9A-9F illustrate various exemplary stages of an alternative embodiment for fabricating the memory cell 10. For example, to fabricate the lower portion of the magnetic switch 120, a suitable wafer 938, such as a SiO₂ deposited wafer, is used. The lower portion of the magnetic component 122 is electroplated onto the wafer 938 through a mold that provides the shape and dimensions of the lower portion of the magnetic component 122. To fabricate such mold, a well 975 is formed in the wafer 938 using common photolithographic and etching (e.g., RIE, wet etch, ion mill, etc.) processes. (FIG. 9A.) Then, a magnetic material 976 is electroplated into the well 975 to the form the lower portion of the magnetic component 122. (FIG. 9B.)

Once the lower portion of the magnetic switch 120 is formed, a layer 978 of a dielectric material, such as Sio₂, SiON, or silicon nitride, is deposited onto the lower portion of the magnetic component 122 using PVD or PECVD, for example. Next, the wafer 938 is planarized using a suitable lapping/polishing technique such as CMP. After planarization, the dielectric layer 978 remains over the lower leg 127. The front and back magnetic pillars 948a, 948b are exposed. (FIG. 9C.)

The wafer 938 is then patterned to form a first layer of coil 924a by using a damascene technique equivalent to that used to form the metal layers in an advanced CMOS fabrication process, for example. (FIGS. 9D-9E.) As shown in FIG. 9E, a single turn coil 924a is illustrated. However, as discussed above, any suitable number of turns may be fabricated without departing from the scope of the present invention. Moreover, the process of forming the first layer of coil 924a may be skipped if only one layer of coil is desired. Once the lower portion of the magnetic component 122 (and first layer of coil 924a) has been formed, the sensor 130 is fabricated using the process discussed above. (FIGS. 5B-5I.)

After the sensor 130 is formed, the upper portion of the magnetic switch 120 is formed similar to the process as described above. That is, first, an insulating layer 960 is deposited onto the wafer 938. (FIG. 9F.) The insulating layer 960 electrically isolates the Hall sensor 132 from the upper magnetic pole 121. A second layer 924b of coils is then patterned and deposited using techniques discussed above. (FIGS. 6A-6E or FIGS. 8A-8E.) Thereafter, the upper portion of the magnetic component 122 is formed using the process discussed above. (FIGS. 7A-7D.) While the layered coil structure has been described in the alternative exemplary embodiment as illustrated in FIGS. 9A-9F, a similar process may be employed to form the first coil layer before the step of forming the sensor 130 as illustrated in FIGS. 5B-5E (i.e., after FIG. 5A but before FIG. 5B).

The processes described above have been selected to be compatible for insertion into a normal CMOS fabrication process, thus being able to use the well established CMOS build to create the active and passive components needed to drive and read the magnetic memory deviced according to the present invention. Those knowledgeable in the art will be able to follow the process of integrating the CMOS fabrication steps and the steps needed to form the magnetic memory device of the current invention.

The magnetic memory device according to the present invention was described in relation to a magnetic switch and a Hall effect sensor. In particular, the advantages of a magnetic component that can retain a magnetic field without any power supplied thereto and a simple sensor for reading the stored magnetic field provides a non-volatile memory device that consumes very little power for operation compared to the electric-based memory devices currently in use.

Additionally, the magnetic switch according to the present invention was described. The advantages of the magnetic switch according to the present invention are numerous. For example, because the magnetic component retains the induced magnetization (M) from the induction coil, the magnetic switch according to the present invention can function as a switch with non-volatile memory.

The magnetic memory device according to the present invention has various applications including, but not limited to, radio frequency identification tags (RFIDs), personal digital assistants (PDAs), cellular phones, and other computing devices. For instance, the magnetic memory device according to the present invention has uses for aerospace/defense, sensors, and RFID applications. The magnetic random access memory of the present invention has been developed for low density radiation hard applications. The magnetic random access memory of the present invention is non-volatile, read/write addressable, and fabricated from radiation hard materials. The applicable and emerging markets include aerospace and defense, such as rad-hard military and radar systems, satellite, and security applications, sensors, and RFID. Sensors in automotive applications, medial equipment like bioelectronics, biosensors, and gas/liquid/energy metering, and seismic monitoring for oil and gas exploration, for example, are all envisioned as potential uses for the present invention. Future growth and technical evolution is anticipated in the pervasive computing, PDA, and display markets as well.

It will be apparent to those skilled in the art that various modifications and variations can be made in the magnetic switch of the present invention without departing from the spirit or scope of the invention. Thus, it is intended that the present invention cover the modifications and variations of this invention provided they come within the scope of the appended claims and their equivalents.

What is claimed is:

1. A memory device, comprising:
a first magnetic portion of a memory bit;
a sensor formed over the first magnetic portion; and
a second magnetic portion of the memory bit formed above the sensor,
wherein the first and second magnetic portions are connected by a third magnetic portion.

2. The memory device of claim 1, wherein a coil is disposed coaxially around the third magnetic portion.

3. The memory device of claim 2, wherein the coil includes a plurality of coil layers.

4. The memory device of claim 1, wherein the first, second and third magnetic portions are made of a soft magnetic material, such as 80:20 NiFe, 45:55 NiFe, or NiFeCo.

5. The memory device of claim 1, wherein the sensor is made from a high electron mobility material, such as GaAs, InP, or a 2DEG composite.

6. The memory device of claim 1, wherein the sensor is made from SiGe.

7. A method of fabricating the memory device of claim 1, that incorporates the use of magnetic pillars to direct the magnetic flux around the magnetic storage device, which reduces the amount of stray magnetic fields, reducing cross-talk with adjacent bits, and strengthens the magnetic flux at the sensor by the reduction of losses.

8. A method of fabricating the memory device of claim 1 that incorporates the use of copper damascene procedures to form the coils.

9. A method of fabricating the memory device of claim 1 that utilizes the metal (aluminum) from one of the metallization layers of a CMOS device to form the coils.

10. A method of fabricating a memory device, comprising:
forming an amorphous GaAs layer over a silicon substrate;
annealing the amorphous GaAs layer; and
forming a crystalline GaAs layer on the amorphous layer.

11. A method of fabricating a memory device, which utilizes ion implant to isolate the sensor, replacing wet chemical etching, allowing for smaller sensor dimensions.
